(19) United States
(12) Patent Application Publication
(10) Pub. No.: US 2014/0266365 A1
(43) Pub. Date: Sep. 18, 2014

(54) LATENCY/AREA/POWER FLIP-FLOPS FOR HIGH-SPEED CPU APPLICATIONS

(71) Applicant: BROADCOM CORPORATION, Irvine, CA (US)

(72) Inventors: Paul Penzes, Irvine, CA (US); Ardavan Moassessi, Laguna Niguel, CA (US)

(73) Assignee: BROADCOM CORPORATION, Irvine, CA (US)

(21) Appl. No.: 13/802,607

(22) Filed: Mar. 13, 2013

(51) Int. Cl. H03K 3/012

(52) U.S. Cl. CPC H03K 3/012
USPC 327/203

(57) ABSTRACT

A circuit for a low latency, low area, and low power flip-flop may include a pass-gate multiplexer that can selectively allow one of input or test data to enter a master cell when a clock signal is low. The master cell may include a first inverter cross-coupled to a second inverter, and may receive the input or test data and may latch and provide at an input node of the slave cell, an inverted input data or the test data, upon a transition of the clock signal to a high state. The slave cell may include a second clock pass-gate and a third inverter that is cross-coupled to a fourth inverter, and may receive the inverted input data or the test data and may latch and provide at an output node, the input data or the test data, upon the transition of the clock signal to a high state.

### TECHNICAL FIELD

The present description relates generally to flip-flops, and more particularly, but not exclusively, to improved latency/area/power flip-flops for high-speed CPU applications.

### BACKGROUND

The state-of-the-art flow of designing Integrated Circuits (e.g., micro-chips) may include specifying the functionality of the chip in a standard hardware programming language such as Verilog, synthesizing/mapping the circuit description into basic gates of a standard cell library using design compiler CAD tools (e.g., Synopsys' Design Compiler), placing and routing the gates netlist using IC compiler CAD tools (e.g., Synopsys' IC Compiler), and finally verifying proper connectivity (e.g., by using layout versus schematic (LVS) software) and functionality of the circuit. While these steps may be important for the final quality of the integrated circuit, for most of the steps, the achievable quality of implementation may be design dependent. For example, a good Verilog code specifying a circuit A may not make an independent circuit B any better. However, an adequate standard cell library may improve all designs that use that standard cell library. In other words, the quality of the standard cell library used in designing a chip may have a far reaching influence on the quality of the chip.

With the advent of technology scaling, higher and higher levels of integration may became possible due to the shrinking device sizes. At the same time, the technology scaling may have provided not only an area scaling but also a delay scaling. According to Moore's Law, chips were doubling their speed every 18 months. While Moore's Law has been applicable for more than 20 years, the technology has reached a point where process scaling may no longer deliver the expected speed increases. This is mainly due to the fact that certain device parameters may have reached atomic scales. This trend can be clearly shown as the technology moves from 28 nm to 20 nm feature size. Similar trends are also foreseen by silicon vendors projecting not only for their current offerings of 20 nm but also for the future 14 nm technologies. As one of the consequences of this speed saturation due to technology scaling, designers may need to work harder at each stage of the design flow to squeeze out the last remaining circuit performance. In other words, even small speed improvements may come at significantly higher design efforts than in the past. In particular, it may be more important than ever to have the best standard cell library possible, as this is one of those key ingredients that may influence many design efforts.

### BRIEF DESCRIPTION OF THE DRAWINGS

Certain features of the subject technology are set forth in the appended claims. However, for purpose of explanation, several embodiments of the subject technology are set forth in the following figures.

FIG. 1A illustrates an example of a low-latency flip-flop and associated clock generator circuits in accordance with one or more implementations.

FIG. 1B illustrates and example of an improved low-latency flip-flop and associated clock generator circuits in accordance with one or more implementations.

FIG. 2 illustrate an example implementation of a non-pass-gate circuit for replacing the pass-gate multiplexer of the improved low-latency flip-flop of FIG. 1B in accordance with one or more implementations.

FIG. 3A illustrates an example of an improved low-latency flip-flop using a non-pass-gate circuit of FIG. 2 in accordance with one or more implementations.

FIG. 3B illustrates an example of an improved low-latency flip-flop with deletion of the last inverter of the flip-flop of FIG. 3A in accordance with one or more implementations.

FIG. 3C illustrates an example of a high speed non-pass-gate multiplexer for the improved low-latency flip-flop of FIG. 3B in accordance with one or more implementations.

FIG. 4A illustrates an example scan flip-flop with similar master and slave cells.

FIG. 4B illustrates examples of an inverting and a non-inverting data cell of a scan flip-flop in accordance with one or more implementations.

FIG. 4C illustrates examples of conceptual clock generator circuits for using with the inverting and a non-inverting data cells of FIG. 4B in accordance with one or more implementations.

FIG. 5A illustrates an example of an implementation of a flip-flop cluster sharing clock generator circuits in accordance with one or more implementations.

FIG. 5B is a table illustrating area reduction of the flip-flop clusters sharing clock generator circuits in accordance with one or more implementations.

FIG. 5C illustrates an example of a layout for the implementation of the flip-flop cluster of FIG. 5A in accordance with one or more implementations.

FIGS. 6A-6B illustrate plots of cell area versus operating frequency of blocks of an ARM CPU and a signal processing block, respectively, using flip-flop clusters in accordance with one or more implementations.

FIG. 7 illustrates an example of an implementation of shared clock generator circuits for the flip-flop cluster of FIG. SA in accordance with one or more implementations.

FIG. 8 illustrates an example method for providing a low-latency flip-flop in accordance with one or more implementations.

FIG. 9 illustrates an example method for providing flip-flop clusters sharing clock generator circuits in accordance with one or more implementations.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced using one or more implementations. In one or more instances, well-known structures and components are shown in block diagram form in order to avoid obscuring the concepts of the subject technology.

FIG. 1A illustrates an example of a low-latency flip-flop 100A and associated clock generator circuits 140 and 150 in accordance with one or more implementations of the subject technology. The low-latency flip-flop (e.g., a scan flip-flop) 100A includes a pass-gate multiplexer 110, a master cell 120, a slave cell 130, the clock generator circuit 140, and the clock generator circuit 150. The pass-gate multiplexer 110 include pass-gates 112 and 114 configured to selectively allow one of input data D or test-input data TI (hereinafter “test data TI”) to enter an input node 121 of master cell 120 when either of the pass-gates 112 or 114 is conducting. The pass-gates 112 and 114 are controlled by a data-enable (DEN) signal, a data-enable bar (DENB) signal, a test-input-enable (TIEN) signal, and a test-input-enable bar (TIENB) signal that are generated by clock generator circuits 140 and 150.

The master cell 120 may include an inverter 122 cross-coupled with an inverter 124 through a clock pass-gate 126. The master cell 120 may receive the input data D or the test data TI and may latch and provide at an input node 131 of the slave cell 130, an inverted replica of the input data D or the test data TI, upon a transition of the clock signal CLK to a logical high state (hereinafter “high”). The slave cell 130 may include a clock pass-gate 132 and an inverter 134 that is cross-coupled to an inverter 136 through a clock pass-gate 138. The slave cell 130 may receive the inverted replica of the input data D or the test data TI and may latch and provide at an output node Q of the slave cell 130, the input data D or the test data TI, upon the transition of the clock signal CLK to high.

The pass-gates 112, 114, 132 and the clock pass-gates 126 and 138 may be substantially similar and may be implemented in CMOS. The pass-gates 126, 132, and 138 may be controlled by the CLK signal and a CLKB signal, which is an inverted replica of the CLK signal. The inverters 122, 124, 134, and 136 may be substantially similar and may be implemented in CMOS. The clock generator circuit 140 may be implemented by a NAND-gate 142 and an inverter 144 and may provide the TIEN and TIENB signals based on the TE signal and the CLKB signal. The clock generator circuit 150 may be implemented by a NOR-gate 152 and an inverter 154 and may provide the DEN and DENB signals based on the TE signal and the CLK signal. In the pass-gate multiplexer 110, the data input D may be selected when TE signal is at a logical low state (hereinafter “low”). This input then may be sampled on the rising edge of the CLK signal producing and output (e.g., an output Q of the flip-flop) on the output node Q of the slave cell 130. The output node Q may be maintained stable till a new clock signal arrives and a possible new value is written into the flip-flop 100A. When the flip-flop 100A is in a scan-mode, TE signal is high and the selected input is TI. This signal then follows the same timing path producing an output on the output node Q. For normal operation, a low TE signal may be of interest. This mode may be the one that determines the minimum latency of the flip-flop, and ultimately the chip's maximum operating frequency.

The low-latency of the flip-flop 100A may result from deletion of a pass-gate (e.g., similar to 132) from master cell 120, which is existent in conventional scan flip-flops. The deletion of the pass-gate from master cell 120 is made possible by design of the clock generator circuits 140 and 150 that allows combining the functionality of the deleted pass-gate with the pass-gate multiplexer 110. The TE and CLK/CLKB signals are combined to provide encoded select signals (e.g., DEN, DENB, TIEN, TIENB) for the pass-gate multiplexer 110. The deletion of the pass-gate from the master cell 120 not only reduces the latency but may also save on the area and power consumption of the flip-flop. This in view of the fact that flip-flops, in particular scan-able flip-flops, may represent about 30-40% of the logic area of many chips. At the same time, for high-speed applications such as Arm/MIPS CPU designs, the latency of the flip-flops (e.g., a setup time+a clock-to-Q time) may represent up to 20% of the flip-flops cycle time. Therefore, the improved latency and area and power saving by the disclosed flip-flops may result in significant improvement in the latency, area and power consumption of the chips using the subject flip-flops.

Another benefit of elimination of the pass-gate from the master cell 120 is that in the flip-flop 100B there is a timing overlap between the master cell 120 and the slave cell 130 that allows a reduced set-up time as the data input D can feed-through directly to the output node Q of the flip-flop. The amount of this overlap may be determined by the arrival of signals DENB/DEN to the pass-gate 112. It is known that N-type gates drive 0 signals well, while P-type gates drive 1 signals well. For example, a proper fully-restoring CMOS gate has a P-transistor pull-up (not an N-type) to drive the output to full 1 level (e.g., supply voltage VDD) and an N-transistor pull-down (not a P-type) to drive the output to a full 0 level (e.g., ground potential GND). Thus, when pass-gate 112 is opening, a 0 is driven mostly through the N transistor controlled by DENB signal and a 1 is driven through the P transistor controlled by the DEN signal. However, because of the inversion delay of DEN (see clock generator circuit 150), signal DENB always arrives early to the pass-gate 112, resulting in lesser master/slave timing overlap for the case when D=0 is written into the flip-flop. At the same time, when D=1 is written to the flip-flop, the late arrival of DEN may allow more timing overlap (which benefits latency).

To make the point more clear, a comparison can be made when a D=1 and a D=0 is written to the flip-flop 100A (e.g., no longer being driven through the pass-gate 112) for the improved flip-flop 100A versus an existing version. For this, we may compare the rise of the signal CLK to the rise of the DEN signal (controlling D=1 being written) and the fall of the CLKB signal to the fall of DENB signal (controlling D=0 being written). For D=1, the clock signal CLK arrives two logic stages earlier than DEN signal (e.g., NOR-gate 152+inverter 154). This way, the writing of D=1 benefits from the master/slave timing overlap. On the other hand, for D=0, the only delay difference between the CLKB signal and the DENB signal may be due to the type of gate being used (e.g., NAND-gate versus a NOR-gate such as 152); and no delay due to logic depth. Therefore, the writing of D=0 may not benefit an much from the slave/master timing overlap. As a result, writing a 0 to the flip-flop 100A may be substantially slower than writing the corresponding 1. This then may manifest itself on the critical path of the flip-flop and adversely affect the timing efficiency of the flip-flop 100A. A further improvement in the flip-flop clock generator circuit 150, as described below, can totally resolve this issue.

FIG. 1B illustrates an example of an improved low-latency flip-flop 100B and associated clock generator circuits 140 and 160 in accordance with one or more implementations of the subject technology. The improved low-latency flip-flop 100B is similar to the low-latency flip-flop 100A of FIG. 1A, except for the pass-gate multiplexer 115 which is improved with respect to the pass-gate multiplexer 110 of FIG. 1A. The improvement can resolve the latency difference for writing 0 and 1 data to the flip-flop 100B. The master cell 120 and the slave cell 130 remain the same as in FIG. 1A. The clock generator circuit 140 remains the same as in FIG. 1A, and the clock generator circuit 150 of FIG. 1A may be improved by adding the inverter 162 to generate the signal DENB bar (DENBB) that is applied to the P-transistor of the pass-gate 116.

Note that this change now delays the controlling signal for writing a D=0 by two logic stage delays (e.g., 154 and 162) compared to the case of flip-flop 100A, and makes it comparable to writing of a D=1. This rebalancing of the overlap window may speed up writing D=0 as well. An implementation of the flip-flop 100B and the associated clock generation circuits 140 and 160 in layout was characterized and used to synthesis and place and route a large block. The results showed that indeed, flip-flop 100B is superior in speed to the flip-flop 100A, which in turn is significantly faster than existing scan flip-flops.

FIG. 2 illustrates an example implementation of a non-pass-gate circuit 210 for replacing the pass-gate multiplexer 115 of the improved low-latency flip-flop of FIG. 1B in accordance with one or more implementations of the subject technology. Looking forward towards the new technologies involving FINFET transistors and beyond, pass-gate input cells in general, and pass-gate input scan flip-flops in particular, may not be desirable. This is because pass-gates may be harder to model in terms of delay at the interface of a state holing element and may involve breaking the continuous diffusion resulting in larger cell area. As a consequence, to be able to preserve the benefit of the flip-flop 100B of FIG. 1B for future process generations, this family of flip-flops may be extended to use a non-pass-gate multiplexer described herein.

The non-pass-gate circuit 210 includes a non-pass-gate multiplexer 215 and an inverter 220. The non-pass-gate multiplexer 215 includes P-transistors (e.g., PMOS) T1-T4 and N-transistors (e.g., NMOS) T5-T8. The transistors T1-T2 and T5-T6 can control test input TI and the transistors T3-T4 and T7-T8 can control data input D. For example, P-transistors T3-T4 can pull a signal at node 212 to a high state when both the DEN signal and the input data D are at a logical low state, and can pull the signal at node 212 to a logical low state when both the DENBB signal and the input data D are at a logical high state. The inverter 220 can be pushed through the circuit to the output of the scan flip-flop as described below. This may help in generating higher-drive strength flip-flop cell variants efficiently.

FIG. 3A illustrates an example of an improved low-latency flip-flop 300A using a non-pass-gate multiplexer 215 of FIG. 2 in accordance with one or more implementations of the subject technology. In the improved low-latency flip-flop 300A, the non-pass-gate multiplexer 215, is the same as in FIG. 2; and a master cell 320 and a slave cell 330 are the same as the master cell 120 and the slave cell 130 of FIG. 1B. The inverter 220 of FIG. 2 is pushed through the master cell 320 and a slave cell 330 to form the output stage of the flip-flop 300A. The clock generator circuits 340 and 360 are the same as the clock generator circuits 140 and 160 of FIG. 1B.

FIG. 3B illustrates an example of an improved low-latency flip-flop 3038 with deletion of the inverter 220 of the flip-flop 300A of FIG. 3A in accordance with one or more implementations of the subject technology. The improved low-latency flip-flop 300B is similar to improved low-latency flip-flop 300A, except that the inverter 220 is deleted. The deletion reduces the size of the flip-flop 300B, for the cases where an inversion would be necessary as dictated by the logic following the output of flip-flop 30013. The clock generator circuits 340 and 360 are the same as in FIG. 3A.

FIG. 3C illustrates an example of a high speed non-pass-gate multiplexer 315 for the improved low-latency flip-flop 30013 of FIG. 3B in accordance with one or more implementations of the subject technology. A further speed improvement applicable to the improved low-latency flip-flop 300B of FIG. 3B may be achieved by doubling up the N-transistor controlled by signal DENBB and the P-transistor controlled by signal DEN (e.g., transistors T3 and T8 of FIG. 2). By doubling these transistors, we can discharge the intermediary node (e.g., node 212) such that when input data D arrives the output of the non-pass-gate multiplexer 315 can transition quicker, resulting in further latency reduction of the flip-flop 300B. It is understood that this scheme is applicable to both non-inverting (e.g., 300B) and inverting (e.g., 300A) versions of the flip-flop.

FIG. 4A illustrates an example scan flip-flop 400A with similar master and slave cells. In the scan flip-flop 400A, a pass-gate multiplexer 410 is similar to pass-gate multiplexer 110 of FIG. 1A, and a slave cell 430 is similar to the slave cell 130 of FIG. 1A. The master cell 420 includes a pass-gate 425 which is eliminated in the implementations of the subject technology to improve latency, area, and power of the subject flip-flops as described above. A further significant area and power reduction can be achieved by implementing a flip-flop cluster as described herein. It is understood that the majority of (e.g., 80%) the exiting high-speed flip-flops are designed based on the scan flip-flop 400A.

FIG. 4B illustrates examples of an inverting data cell 450 and a non-inverting data cell 460 of a scan flip-flop in accordance with one or more implementations of the subject technology. It is possible to cluster several scan flip-flops into groups of 4 or more flip-flops that can share some of the common circuitry and change the design of the master/slave cells (e.g., latches) to save further area/power. This can be achieved by designing a monolithic standard cell with these new properties. This would have not been possible without such a merged circuitry, as the design tools may have no way of inferring the possible commonalities within the internals of the standard cells. For simplicity, a design where 2 bits (e.g., two flip-flops) are merged are described first and then the generalization for more flip-flops are explained. As the number of clustered flip-flop increase so does the resulting area saving. In the following, the description is based on first presenting the data cells and the clock generator cells separately, and then, composing these cells into a final monolithic circuit. Two types of data cells 450 and 460 are described. The data cell 450 logically inverts an input and data cell 460 does not invert the input. The data element 450 may combine the pass-gate multiplexer 410 and the master cell 420 of FIG. 4A. The data cell 460 is similar to the data cell 450 except for an additional inverter 465 at the output stage of the data cell 460.

FIG. 4C illustrates examples of conceptual clock generator circuits 400C for using with the inverting and a non-inverting data cells 450 and 460 of FIG. 413 in accordance with one or more implementations of the subject technology. The clock generator circuits 400C generate the control signals that can be shared among the various flip-flops of a flip-flop cluster, such as TE/TEB and CLK/CLKB signals. To keep the flip-flop cluster logically equivalent to a set of individual flip-flops with the given data cells a pulse generation scheme may be used. The pulse flip-flops are known in the art but are typically applied to improve speed of a design, not area/power as in the disclosed flip-flop cluster. Furthermore, the pulse flip-flops have not been applied in clusters of flip-flops as presented here. The clock generator circuits 400C include the clock generator cell 470 that includes logic gates for providing the clock signals CLKB and CLK from a pre-clock signal preCLK. The clock generator cell 470 may generate the clock signals CLKB and CLK with a pulse-width that is substantially independent of a slope of the pre-clock signal. The TEB signal is generated by simply inverting the preCLK signal.

FIG. 5A illustrates an example of an implementation of a flip-flop cluster 500A sharing clock generator circuits in accordance with one or more implementations of the subject technology. The flip-flop cluster 500A includes inverting and non-inverting data cells 510 and 520 that are respectively similar to the inverting and non-inverting data cells 450 and 460 of FIG. 4B. The inverting and non-inverting data cells 510 and 520 and many other inverting and non-inverting data cells (not shown in FIG. 5A for simplicity) of the flip-flop cluster 500A may share the clock generator circuit 530 that can provide the control signals CLK, CLKB, TE, and TEB. The flip-flop cluster may be implemented for various flip-flop groupings, including 4-way, 6-way, 8-way, 10-way, 12-way, 14-way, and 16-way grouping. The grouping of the example flip-flop cluster 500A is a two-way grouping.

FIG. 5B is table 500B illustrating area reduction of the flip-flop clusters sharing clock generator circuits in accordance with one or more implementations of the subject technology. As shown in the table 500B, the two-way grouping may not save area, whereas increasing grouping size of the flip-flop cluster up to 20-way grouping may result in an increased area reduction up to approximately 35%. The two-way implementation is not seen to save area/power as there are not enough data cells to amortize the fixed area of the dock generator cell. At the other extreme of the scale, it is seen that beyond the 16-way case, the area reduction gains may saturate so for a large cluster such as a 32 bits (e.g., 32 flip-flops) one can use two 16-way clusters and achieve an area saving very close to the area saving of a 32-way implementation. By doing this cut-off beyond 16-way grouping, the number of library cells may be kept low so that it can speed up implementation and release of the resulting chip.

FIG. 5C illustrates an example of a layout 500C for the implementation of the flip-flop cluster 500A of FIG. 5A in accordance with one or more implementations of the subject technology. The layout 500C is for a four-way grouping and includes four single-height data elements 522, 524, 526, and 528 and one double-height clock generator element 540. In practice there can be multiple (e.g., 16) single height elements each representing a flip-flop data cell (e.g., inverting and non-inverting data cells such as 510 and 520 of FIG. 5A). The double-height clock generator element represent a clock generator cell (e.g., 530 of FIG. 5A) positioned between four single-height data elements 522, 524, 526, and 528.

In the layout 5000 the clock generator element 540 is implemented in double height so that the width of the clock generator element 540 does not need to be matched to that of the data elements 522, 524, 526, and 528, resulting in a more compact layout. At the same time, the layout design may share a common power supply rail VDD that can eliminate launch-to-capture voltage variations, a phenomenon that can be the case for randomly placed flip-flops operating on independent VDD rails. Also, the close proximity of these circuits may eliminate global variability, something that may deteriorate the speed of randomly placed flip-flops. For larger clusters, the data element pairs may be added alternating between the left and right of the presented structure (e.g., layout 500C), keeping the design as symmetric as possible in reference to the clock generator element 540. This will ensure close to equal-length clock wires which can further reduce variability and mismatch.

Besides the area saving of the flip-flop cluster, the other essential thing for the usefulness of the disclosed design is the amount of “state coverage” these flip-flops provide in an actual implementation. The term “state coverage” may be defined as the percentage of the clustered flip-flops that are being picked up by the synthesis/P&R tools. The described family of flip-flop clusters are tried on various circuits and confirmed experimentally that the “state coverage” is about 80% and may reduce to approximately 65% at the highest speed (e.g., due to requirement of larger and more diverse drive strength at higher speeds). This may result in an about 10% area and leakage power savings at block level. This experimental result can be anticipated via, the following hand calculation. With a given original area of 1, after applying the flip-flop cluster cells the new area is reduced to 0.65 (logic cells that are not scan flip-flops)+0.35 (scan flip-flops)*(0.2 (not covered)+0.8 (state coverage))*0.7 (average area reduction)=0.916, which shows about 8% area reduction compared to the base case. The hand-calculated result is almost close to the experimentally observed 10%.

FIGS. 6A-6B illustrate plots of cell area versus operating frequency of blocks of an ARM CPU and a signal processing block, respectively, using flip-flop clusters in accordance with one or more implementations of the subject technology. When the area of a circuit block is reduced (as described above with respect to FIG. 5C), even if not on the critical path, the length of wires including critical wires may go down. That in turn may make timing closure easier for the same target operating frequency or may allow for a higher target operating frequency at the same effort level. Both of these effects are exemplified in the plots 600A and 600B, respectively, showing cell area versus operating frequency of a large block within the ARM A15 CPU, and a signal processing block. As seen from the plots the graphs 612 and 622 corresponding to the clustered flip-flops are well under the graphs 610 and 620 corresponding to non-clustered flip-flops, and also shifting slightly to the right as the operating frequency increases.

FIG. 7 illustrates an example of an implementation 700 of shared clock generator circuit for the flip-flop cluster 500A of FIG. 5A in accordance with one or more implementations of the subject technology. The implementation 700 is a practical implementation of the conceptual clock generator circuits 400C of FIG. 4C. The width of the pulse generated by the clock generator circuit 700 may depend on the odd-number (e.g., 3 in this case) and delay of the inverters (even number of inverters would not be functional). The clock pulse width is designed to be less dependent on the slope of the clock (e.g., preCLK signal), as such, an inversion (via inverter 710) may be added to the input of the clock generator circuit 700 to decouple preCLK signal from the CLK/CLKB signals. To make the clock generator circuit 700 logically equivalent to the original circuit (e.g., conceptual clock generator circuits 400C), the NAND-gate of the original circuit is replaced with a NOR-gate 740 and an inverter 750. Furthermore, two more changes to the original delay path of the three inverters are made. The first change is adding an always-open series pass-gate 720, and the second change is that one of the inverters (e.g., 730) is changed to have two series N and P transistors, respectively. The second change may allow added delay in an area efficient way. The pass-gates may not change the signal polarity and are used only to provide delay while providing better match across the process-voltage-temperatures (PVTs) to the data input D and test input TI paths. As seen from the depiction of the data cells 450 and 460 of FIG. 4B, both the data input D and test input TI pass through two series pass-gates. This is then mimicked in the implementation 700. Via these changes a minimum width pulse, wide enough for correct functionality across all PVTs, can be achieved.

FIG. 8 illustrates an example method 800 for providing a low-latency flip-flop in accordance with one or more implementations of the subject technology. The method 800 may begin with operation block 810, where a pass-gate multiplexer (e.g., 110 of FIG. 1A) may be coupled to a master cell (e.g., 120 of FIG. 1A) that is coupled to a slave cell (e.g., 130 of FIG. 1A). The pass-gate multiplexer may be configured to selectively allow one of input data (e.g., D of FIG. 1A) or test data (e.g., TI of FIG. 1A) to enter an input node (e.g., 121 of FIG. 1A) of the master cell when a clock signal (e.g., CLK of FIG. 1A) is at a logical low state.

At operation block 820, the master cell may be formed by cross-coupling a first inverter (e.g., 122 of FIG. 1A) to a second inverter (e.g., 124 of FIG. 1A) through a first clock pass-gate (e.g., 126 of FIG. 1A). The master cell may be configured to receive the input data or the test data and to latch and provide at an input node (e.g., 131 of FIG. 1A) of the slave cell, an inverted replica of the input data or the test data, upon a transition of the clock signal to a logical high state.

At operation block 830, the slave cell may be formed by coupling a second clock pass-gate (e.g., 132 of FIG. 1A) to a third inverter (e.g., 134 of FIG. 1A) that is cross-coupled to a fourth inverter (e.g., 136 of FIG. 1A) through a third clock pass-gate (e.g., 138 of FIG. 1A). The slave cell may be configured to receive the inverted replica of the input data or the test data and to latch and provide at an output node (e.g., Q of FIG. 1A) of the slave cell the input data or the test data, upon the transition of the clock signal to a logical high state.

At operation block 840, control signals (e.g., DEN, DENB, TIEN, and TIENB of FIG. 1A) for controlling the pass-gate multiplexer may be provided by using clock-logic circuits (e.g., 140 and 150 of FIG. 1A). The clock-logic circuits may be configured to allow substantially similar master/slave timing overlap for zero and one values of the input data.

FIG. 9 illustrates an example method 900 for providing flip-flop clusters sharing clock generator circuits in accordance with one or more implementations of the subject technology. The method 900 may begin with operation block 910, where a plurality of inverting data cells (e.g., 450 of FIG. 4B), may be formed, each including a pass-gate multiplexer (e.g., 410 of FIG. 4A), a first clock pass-gate (e.g., 425 of FIG. 4A), and a first inverter that is cross-coupled to a second inverter through a second clock pass-gate.

At operation block 920, each inverting data cell (e.g., 460 of FIG. 4B) may be configured to receive input data or test data and to provide at an output node of the inverting data cell, an inverted replica of the input data or the test data, upon the transition of a clock signal (e.g., CLK of FIG. 4B), to a logical high state, and to latch the inverted replica of the input data or the test data upon the transition of a clock signal to a logical low state.

At operation block 930, a plurality of non-inverting data cells (e.g., 460 of FIG. 4B), may be formed. Each of the non-inverting data cells may include an inverting data cell followed by a third inverter (e.g., 465 of FIG. 4B). At operation block 940, the flip-flop cluster (e.g., 500A of FIG. 5A) may be formed by providing a clock generator cell (e.g., 530 of FIG. 5A) that is shared by the multiple inverting data cells (e.g., 510 of FIG. 5A) and the multiple non-inverting data cells (e.g., 520 of FIG. 5A).

At operation block 950, the pass-gate multiplexer may be configured to selectively allow passage of one of the input data or the test data to an output node of the pass-gate multiplexer. At operation block 960, the clock generator cell may be configured to generate control signals to control operation of the pass-gate multiplexer.

Those of skill in the art would appreciate that the various illustrative blocks, modules, elements, components, and methods described herein may be implemented as electronic hardware, computer software, or combinations of both. To illustrate this interchangeability of hardware and software, various illustrative blocks, modules, elements, components, and methods have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

A phrase such as “an aspect” does not imply that such aspect is essential to the subject technology or that such aspect applies to all configurations of the subject technology. A disclosure relating to an aspect may apply to all configurations, or one or more configurations. An aspect may provide one or more examples of the disclosure. A phrase such as an “aspect” may refer to one or more aspects and vice versa. A phrase such as an “embodiment” does not imply that such embodiment is essential to the subject technology or that such embodiment applies to all configurations of the subject technology. A disclosure relating to an embodiment may apply to all embodiments, or one or more embodiments. An embodiment may provide one or more examples of the disclosure. A phrase such an “embodiment” may refer to one or more embodiments and vice versa. A phrase such as a “configuration” does not imply that such configuration is essential to the subject technology or that such configuration applies to all configurations of the subject technology. A disclosure relating to a configuration may apply to all configurations, or one or more configurations. A configuration may provide one or more examples of the disclosure. A phrase such as a “configuration” may refer to one or more configurations and vice versa.

The word “exemplary” is used herein to mean “serving as an example, instance, or illustration,” Any embodiment described herein as “exemplary” or as an “example” is not necessarily to be construed as preferred or advantageous over other embodiments. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A circuit for a low latency, low area, and low power flip-flop, the circuit comprising:
a pass-gate multiplexer coupled to a master cell that is coupled to a slave cell, the pass-gate multiplexer configured to selectively allow one of input data or test data to enter an input node of the master cell when a clock signal is at a logical low state;
the master cell including a first inverter cross-coupled to a second inverter through a first clock pass-gate, the master cell configured to receive the input data or the test data and to latch and provide at an input node of the slave cell, an inverted replica of the input data or the test data, upon a transition of the clock signal to a logical high state;
the slave cell including a second clock pass-gate and a third inverter that is cross-coupled to a fourth inverter through a third clock pass-gate, the slave cell configured to receive the inverted replica of the input data or the test data and to latch and provide at an output node of the slave cell, the input data or the test data, upon the transition of the clock signal to a logical high state; and
a clock-logic circuit to provide control signals for controlling the pass-gate multiplexer, wherein the clock-logic circuit is configured to allow substantially similar master/slave timing overlap for zero and one values of the input data.

2. The circuit of claim 1, wherein the low-latency of the flip-flop results from combining functionality of a deleted dock pass-gate from the master cell with the pass-gate multiplexer.

3. The circuit of claim 2, wherein:
the clock pass-gate is configured to provide a data-enable (DEN) signal and a DEN-bar (DENB) signal,
the DENB signal is an inverted replica of the DEN signal,
the DEN signal is provided by a combination of a NOR gate and an inverter gate, and
The NOR gate input signals include the clock signal and a test-enable (TE) signal.

4. The circuit of claim 3, wherein:
data-path switches of the pass-gate multiplexer are controlled by the DEN signal and the DENB signal,
the data-path switches of the pass-gate multiplexer comprises a P-transistor switch (P-switch) and an N-transistor switch (N-switch), and
the P-switch is controlled by the DEN signal, and the N-switch is controlled by the DENB signal.

5. The circuit of claim 4, wherein the pass-gate multiplexer is replaced with a non-pass-gate multiplexer and an inverter circuit, wherein the non-pass-gate multiplexer is pulled to a logical high state when both the DEN signal and the input data are at a logical low state, and pulled to a logical low state when both the DENB signal and the input data are at a logical high state.

6. The circuit of claim 5, wherein:
the inverter circuit is moved from the non-pass-gate multiplexer to the output node of the slave cell, and
a further saving in chip area of the flip-flop is achieved by removing the inverter circuit if the flip-flop is implemented with a following logic circuit that dictates an inversion.

7. The circuit of claim 5, wherein:
a further speed improvement of the flip-flop is achieved by doubling up a P-switch and an N-switch of the non-pass-gate multiplexer, and
the doubled-up P-switch being controlled by the DEN signal and the doubled-up N-switch being controlled by the DENB signal.

8. A circuit for a flip-flop cluster with reduced area and power, the circuit comprising:
a plurality of inverting data cells, each including a pass-gate multiplexer, a first clock pass-gate, and a first inverter that is cross-coupled to a second inverter through a second clock pass-gate, each inverting data cell configured to receive input data or test data and to provide at an output node of the inverting data cell, an inverted replica of the input data or the test data, upon the transition of a clock signal to a logical high state, and to latch the inverted replica of the input data or the test data upon the transition of a clock signal to a logical low state;
a plurality of non-inverting data cells, each including an inverting data cell of the plurality of inverting data cells followed by a third inverter; and
a clock generator cell shared by the plurality of inverting data cells and the plurality of non-inverting data cells to form the flip-flop cluster, wherein
the pass-gate multiplexer is configured to selectively allow passage of one of the input data or the test data to an output node of the pass-gate multiplexer, and
the clock generator cell is configured to generate control signals to control operation of the pass-gate multiplexer.

9. The circuit of claim 8, wherein the control signals include a test-enable (TE) signal, and a TE-bar (TEB) signal that is an inverted replica of the TE signal, and wherein the clock generator cell is further configured to generate the clock signal from a pre-clock signal, and wherein the clock generator cell is further configured to generate the clock signal with a pulse-width that is substantially independent of a slope of the pre-clock signal.

10. The circuit of claim 8, wherein the flip-flop cluster is implemented by using a layout that comprises single-height data elements and double-height clock generator elements, each double-height clock generator element being positioned between four single-height data elements, wherein single-height data elements on each side of the double-height clock generator elements comprise one inverting data cell and one non-inverting data cell, and wherein the single-height data elements on each side of the double-height clock generator element share a middle power supply line.

11. A method for providing a low latency, low area, and low power flip-flop, the method comprising:
coupling a pass-gate multiplexer to a master cell that is coupled to a slave cell, and configuring the pass-gate multiplexer to selectively allow one of input data or test data to enter an input node of the master cell when a clock signal is at a logical low state;
forming the master cell by cross-coupling a first inverter to a second inverter through a first clock pass-gate, and configuring the master cell to receive the input data or the test data and to latch and provide at an input node of the slave cell, an inverted replica of the input data or the test data, upon a transition of the clock signal to a logical high state;
forming the slave cell by coupling a second clock pass-gate to a third inverter that is cross-coupled to a fourth inverter through a third clock pass-gate, and configuring the slave cell to receive the inverted replica of the input data or the test data and to latch and provide at an output node of the slave cell, the input data or the test data, upon the transition of the clock signal to a logical high state; and
providing, by using a clock-logic circuit, control signals for controlling the pass-gate multiplexer, and configuring the clock-logic circuit to allow substantially similar master/slave timing overlap for zero and one values of the input data.

12. The method of claim 11, wherein the low-latency of the flip-flop results from combining functionality of a deleted clock pass-gate from the master cell with the pass-gate multiplexer.

13. The method of claim 12, further comprising:
configuring the clock pass-gate to provide a data-enable (DEN) signal and a DEN-bar (DENB) signal, the DENB signal being an inverted replica of the DEN signal;
providing the DEN signal by a combination of a NOR gate and an inverter gate; and
including in the NOR gate input signals the clock signal and a test-enable (TE) signal.

14. The method of claim 13, further comprising:
controlling data-path switches of the pass-gate multiplexer by the DEN signal and the DENB signal, the data-path switches of the pass-gate multiplexer comprising a P-transistor switch (P-switch) and an N-transistor switch (N-switch); and
controlling the P-switch and the N-switch, respectively, by the DEN signal and the DENB signal.

15. The method of claim 14, further comprising:
replacing the pass-gate multiplexer with a non-pass-gate multiplexer and an inverter circuit;
pulling the non-pass-gate multiplexer to a logical high state when both the DEN signal and the input data are at a logical low state; and
pulling the non-pass-gate multiplexer to a logical low state when both the DENS signal and the input data are at a logical high state.

16. The method of claim 15, further comprising:
moving the inverter circuit from the non-pass-gate multiplexer to the output node of the slave cell; and
achieving a further saving in chip area of the flip-flop by removing the inverter circuit if the flip-flop is implemented with a following logic circuit that dictates an inversion.

17. The method of claim 15, further comprising:
achieving a further improvement of speed of the flip-flop by doubling up a P-switch and an N-switch of the non-pass-gate multiplexer; and
controlling the doubled-up P-switch and the doubled-up N-switch, respectively, by the DEN signal and the DENB signal.

18. A method for providing a flip-flop cluster with reduced area and power, the method comprising:
forming a plurality of inverting data cells, each including a pass-gate multiplexer, a first clock pass-gate, and a first inverter that is cross-coupled to a second inverter through a second clock pass-gate;
configuring each inverting data cell to receive input data or test data and to provide at an output node of the inverting data cell, an inverted replica of the input data or the test data, upon the transition of a clock signal to a logical high state, and to latch the inverted replica of the input data or the test data upon the transition of a clock signal to a logical low state;
forming a plurality of non-inverting data cells, each including an inverting data cell of the plurality of inverting data cells followed by a third inverter;
forming the flip-flop cluster by providing a clock generator cell that is shared by the plurality of inverting data cells and the plurality of non-inverting data cells;
configuring the pass-gate multiplexer to selectively allow passage of one of the input data or the test data to an output node of the pass-gate multiplexer; and
configuring the clock generator cell to generate control signals to control operation of the pass-gate multiplexer.

19. The method of claim 18, wherein the control signals include a test-enable (TE) signal, and a TE-bar (TEB) signal that is an inverted replica of the TE signal, and further comprising configuring the clock generator cell to generate the clock signal from a pre-clock signal, and to generate the clock signal with a pulse-width that is substantially independent of a slope of the pre-clock signal.

20. The method of claim 18, further comprising implementing the flip-flop cluster using a layout that comprises single-height data elements and double-height clock generator elements, each double-height clock generator element being positioned between four single-height data elements, wherein single-height data elements on each side of the double-height clock generator elements comprise one inverting data cell and one non-inverting data cell, and wherein the single-height data elements on each side of the double-height clock generator element share a middle power supply line.
